(19) United States
(12) Patent Application Publication
(10) Pub. No.: US 2026/0107816 A1
(43) Pub. Date: Apr. 16, 2026

(54) SEMICONDUCTOR PACKAGE

(71) Applicant: SAMSUNG ELECTRONICS CO., LTD., Suwon-si (KR)

(72) Inventor: Jiho LEE, Suwon-si (KR)

(73) Assignee: SAMSUNG ELECTRONICS CO., LTD., Suwon-si (KR)

(21) Appl. No.: 19/237,869

(22) Filed: Jun. 13, 2025

(30) Foreign Application Priority Data
Oct. 16, 2024 (KR) 10-2024-014223

(51) Int. Cl. H01L 23/00; H01L 23/31; H01L 23/48; H01L 25/18; H10B 80/00; H10D 80/30

(52) U.S. Cl. CPC H10W 72/90; H10B 80/00; H10D 80/30; H10W 74/111; H10W 90/00; H10W 20/20; H10W 80/312; H10W 80/327; H10W 90/26; H10W 90/297; H10W 90/792

(57) ABSTRACT

A semiconductor package may include a buffer die, memory die stack units, each of which may include memory dies stacked in a vertical direction, stacked in the vertical direction on the buffer die, and a molding member on the buffer die and covering sidewalls of the memory die stack units. A gap may be between a first memory die and a second memory die over the first memory die among the memory dies of each of the memory die stack units. The molding member may fill the gap.

### CROSS-REFERENCE TO RELATED APPLICATION

This application claims priority under 35 U.S.C. § 119 to Korean Patent Application No. 10-2024-0141223, filed on Oct. 16, 2024, in the Korean Intellectual Property Office, the disclosure of which is incorporated by reference herein in its entirety.

### BACKGROUND

### 1. Field

The disclosure relates to a semiconductor package, and more particularly, to a multi-chip package including a plurality of stacked chips.

### 2. Description of Related Art

A high bandwidth memory (HBM) package may include a plurality of memory chips stacked on a logic chip in a vertical direction, and the memory chips may be bonded to each other by a bonding layer. If the bonding state between the memory chips is good, the HBM package may have enhanced performance, and thus a method of enhancing the bonding state between the memory chips has been studied.

### SUMMARY

Example embodiments provide a semiconductor package which may have enhanced electrical characteristics.

According to an aspect of the disclosure, a semiconductor package includes: a buffer die; memory die stack units stacked in a vertical direction on the buffer die, each of the memory die stack units including memory dies stacked in the vertical direction; and a molding member on the buffer die, the molding member covering sidewalls of the memory die stack units, wherein at least one gap is between a first memory die, from among the memory dies of the memory die stack units, and a second memory die, from among the memory dies of the memory die stack units, the second memory die being over or under the first memory die in the vertical direction, wherein the first memory die includes at least one trench that at least partially defines the at least one gap, and wherein the molding member is in the at least one gap.

According to an aspect of the disclosure, a semiconductor package includes: a buffer die; a first memory die stack unit including first memory dies stacked in a vertical direction on the buffer die; a second memory die stack unit including second memory dies stacked in the vertical direction on the first memory die stack unit; and a molding member on the buffer die, the molding member covering a sidewall of the first memory die stack unit and a sidewall of the second memory die stack unit, wherein at least one gap is between the second memory dies, wherein at least one of the second memory dies includes at least one trench that at least partially defines the at least one gap, and wherein the molding member is in the at least one gap.

According to an aspect of the disclosure, a semiconductor package includes: a buffer die; middle core die stack units stacked in a vertical direction on the buffer die, each of the middle core die stack units including middle core dies stacked in the vertical direction; a top core die stacked on the middle core die stack units; and a molding member on the buffer die, the molding member covering sidewalls of the middle core die stack units and the top core die, wherein each of the middle core dies includes: a first substrate; a first bonding layer on a lower surface of the first substrate, the first bonding layer including a first bonding pad; and a second bonding layer on an upper surface of the first substrate, the second bonding layer including a second bonding pad, wherein at least one first gap is between an upper surface of the second bonding layer of a first middle core die, from among the middle core dies, and a lower surface of the first bonding layer of a second middle core die, from among the middle core dies, wherein the first middle core die or the second middle core die includes at least one first trench that at least partially defines the at least one gap, and wherein the molding member is in the at least one first gap.

According to one or more example embodiments, a semiconductor package may include a plurality of semiconductor chips stacked in the vertical direction, and no voids may be disposed between the semiconductor chips so that the bonding force between the semiconductor chips may be enhanced. The trenches for preventing the voids may be formed only on some of the semiconductor chips, and thus the cost for forming the trenches may be reduced.

### BRIEF DESCRIPTION OF DRAWINGS

FIG. 1 is a vertical cross-sectional view illustrating a semiconductor package in accordance with example embodiments.

FIG. 2 is a horizontal cross-sectional view illustrating a semiconductor package in accordance with example embodiments.

FIGS. 3 to 12 are cross-sectional views and a plan view illustrating a method of manufacturing a semiconductor package in accordance with example embodiments.

FIGS. 13 to 17 are cross-sectional views illustrating semiconductor packages in accordance with example embodiments.

FIG. 18 is a cross-sectional view illustrating an electronic device in accordance with example embodiments.

### DETAILED DESCRIPTION

Hereinafter, non-limiting example embodiments of the disclosure will be explained in detail with reference to the accompanying drawings.

It will be understood that, although the terms “first,” “second,” and/or “third” may be used herein to describe various elements, components, regions, layers, and/or sections, these elements, components, regions, layers, and/or sections should not be limited by these terms. These terms are only used to distinguish one element, component, region, layer, or section from another region, layer, or section. Thus, a first element, component, region, layer, or section discussed below could be termed a second or third element, component, region, layer, or section without departing from the scope of the disclosure.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

Hereinafter, a direction substantially parallel to an upper surface of a wafer or a substrate may be referred to as a horizontal direction, and a direction substantially perpendicular to the upper surface of the wafer or the substrate may be referred to as a vertical direction.

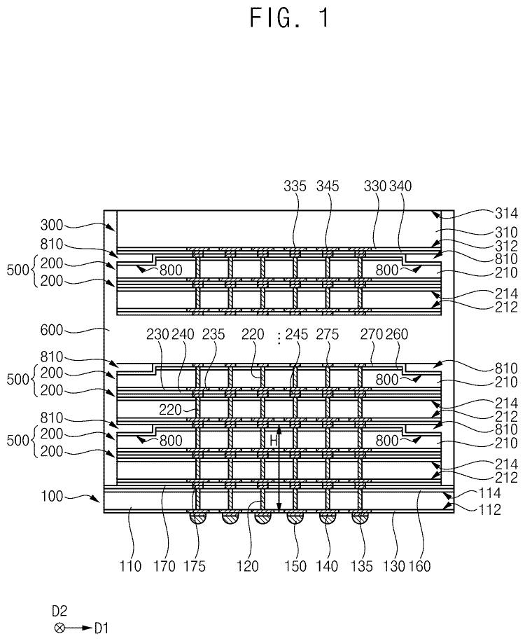

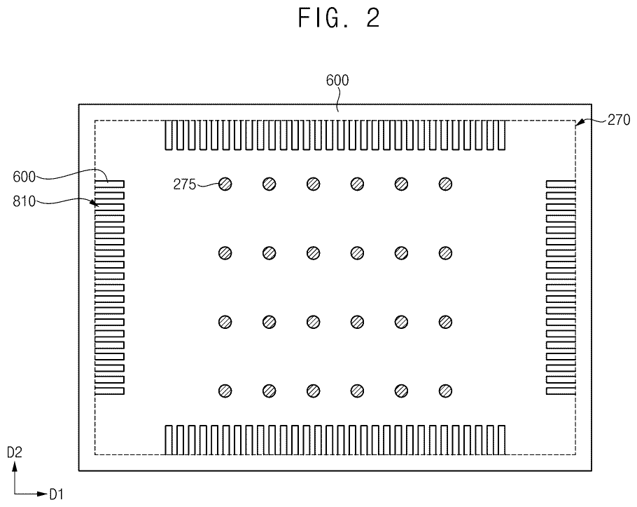

FIGS. 1 and 2 are a vertical cross-sectional view and a horizontal cross-sectional view, respectively, illustrating a semiconductor package in accordance with example embodiments. Particularly, FIG. 2 is a horizontal cross-sectional view at a height H from a lower surface of a second insulating interlayer included in a first semiconductor chip.

Referring to FIGS. 1 and 2, the semiconductor package may include a first semiconductor chip 100, a plurality of semiconductor chip stack units 500, a third semiconductor chip 300 stacked on the first semiconductor chip 100 in the vertical direction, and a molding member 600 on the first semiconductor chip 100 and covering the semiconductor chip stack units 500 and the third semiconductor chip 300.

Each of the semiconductor chip stack units 500 may include a plurality of second semiconductor chips 200 stacked in the vertical direction. In example embodiments, the semiconductor package may be a high bandwidth memory (HBM) package.

In example embodiments, the first semiconductor chip 100 may be a buffer die, and may include a logic device (e.g., a controller). Each of the second semiconductor chips 200 and the third semiconductor chip 300 may be a core die, and may include a volatile memory device (e.g., a dynamic random-access memory (DRAM) device, a static random-access memory (SRAM) device, etc.), or a non-volatile memory device (e.g., a flash memory device, an electrically erasable programmable read-only memory (EEPROM) device, etc.). Each of the second semiconductor chips 200 may also be referred to as a middle core die, and the third semiconductor chip 300 may also be referred to as a top core die.

Additionally, the first semiconductor chip 100 may also be referred to as a logic chip or logic die, and each of the second semiconductor chips 200 and the third semiconductor chip 300 may also be referred to as a memory chip or a memory die. The semiconductor chip stack unit 500 may also be referred to as a memory chip stack unit, a memory die stack unit, or a middle core die stack unit.

In example embodiments, each of the first semiconductor chips 100, the second semiconductor chips 200, and the third semiconductor chip 300 may have a shape of a rectangular parallelepiped, and thus may have a shape of a rectangle in a plan view.

The first semiconductor chip 100 may include a first substrate 110 having a first surface 112 and a second surface 114 opposite to each other in the vertical direction, at least one first through electrode structure 120 extending through the first substrate 110, a first insulating interlayer and a second insulating interlayer 130 sequentially stacked in the vertical direction beneath the first surface 112 of the first substrate 110, at least one conductive pad 140 beneath the second insulating interlayer 130, at least one first conductive connection member 150 beneath the at least one conductive pad 140, a first protective pattern structure 160 on the second surface 114 of the first substrate 110, and a first bonding layer 170 on the first protective pattern structure 160.

The first substrate 110 may include a semiconductor material such as, for example, silicon, germanium, silicon-germanium, or a III-V group compound semiconductor such as, for example, GaP, GaAs, GaSb, etc. In example embodiments, the first substrate 110 may be a silicon-on-insulator (SOI) substrate or a germanium-on-insulator (GOI) substrate.

A circuit device (e.g., a logic device) may be disposed beneath the first surface 112 of the first substrate 110. The circuit device may include circuit patterns, which may be covered by the first insulating interlayer.

The second insulating interlayer 130 may contain a first wiring structure 135 therein. The first wiring structure 135 may include, for example, wirings, vias, contact plugs, etc., and FIG. 1 shows only a single layer for the first wiring structure 135 in order to avoid complexity of the drawing.

The first insulating interlayer and the second insulating interlayer 130 may include, for example, silicon oxide, or a low-k dielectric material such as, for example, an oxide doped with carbon or fluorine. The wirings, the vias, the contact plugs, etc., may include a conductive material such as, for example, a metal, a metal nitride, a metal silicide, etc.

The at least one conductive pad 140 may be disposed under the second insulating interlayer 130, and may contact the first wiring structure 135 to be electrically connected thereto. In example embodiments, a plurality of conductive pads 140 may be spaced apart from each other in the horizontal direction.

In example embodiments, the conductive pad 140 may include a first seed pattern and first and second conductive patterns sequentially stacked downwardly in the vertical direction from the second insulating interlayer 130. The first seed pattern may include, for example, titanium, and the first and second conductive patterns may include, for example, nickel and copper, respectively.

The first conductive connection member 150 may contact a lower surface of the conductive pad 140. The conductive connection member 150 may be, for example, a conductive bump. The conductive connection member 150 may include a metal such as, for example, tin, or solder that is a tin alloy such as tin/silver, tin/copper, tin/indium, tin/silver/copper, etc.

The at least one first through electrode structure 120 may extend through the first substrate 110 in the vertical direction. A portion of the first through electrode structure 120 may protrude upwardly in the vertical direction, which may be referred to as a protrusion portion, and a sidewall of the protrusion portion of the first through electrode structure 120 may be covered by the first protective pattern structure 160. A plurality of first through electrode structures 120 may be spaced apart from each other in the horizontal direction. In example embodiments, the first through electrode structure 120 may include a first through electrode extending in the vertical direction, a first barrier pattern covering a sidewall of the first through electrode, and a first insulation pattern covering an outer sidewall of the first barrier pattern. However, in an example embodiment, the first insulation pattern may not cover an upper portion of the outer sidewall of the first barrier pattern.

The first through electrode may include a metal such as, for example, copper, aluminum, etc., the first barrier pattern may include a metal nitride such as, for example, titanium nitride, tantalum nitride, etc., and the first insulation pattern may include an oxide such as, for example, silicon oxide or an insulating nitride (e.g., silicon nitride).

In an example embodiment, the first through electrode structure 120 may extend through the first protective pattern structure 160, the first substrate 110, and the first insulating interlayer to contact the first wiring structure 135, and may be electrically connected to the first conductive pad 140 by the first wiring structure 135.

Alternatively, the first through electrode structure 120 may extend through the first protective pattern structure 160, the first substrate 110, the first insulating interlayer, and the second insulating interlayer 130 to contact the conductive pad 140, and may be electrically connected thereto. Alternatively, the first through electrode structure 120 may extend through the first protective pattern structure 160 and the first substrate 110 to contact one of the circuit patterns included in the circuit device covered by the first insulating interlayer, and may be electrically connected to the conductive pad 140 by the one of the first circuit patterns and the first wiring structure 135.

The first protective pattern structure 160 may be disposed on the second surface 114 of the first substrate 110, and may surround the protrusion portion of the first through electrode structure 120. In an example embodiment, the first protective pattern structure 160 may contact an outer sidewall of an upper portion of the first barrier pattern of the first through electrode structure 120.

In example embodiments, the first protective pattern structure 160 may include a first protective pattern and a second protective pattern sequentially stacked in the vertical direction on the second surface 114 of the first substrate 110. A portion of the first protective pattern adjacent to the first through electrode structure 120 may protrude upwardly in the vertical direction, and an upper surface of the portion of the first protective pattern 161 may be substantially coplanar with an upper surface of the first through electrode structure 120. An outer sidewall of the portion of the first protective pattern 161 may be covered by the second protective pattern.

The first protective pattern may include an oxide such as, for example, silicon oxide, and the second protective pattern may include an insulating nitride such as, for example, silicon nitride.

The first bonding layer 170 may contain at least one first bonding pad 175 therein. In example embodiments, a plurality of first bonding pads 175 may be spaced apart from each other in the horizontal direction, and the first bonding pads 175 may contact upper surfaces of the first through electrode structures 120, respectively.

In example embodiments, the first bonding layer 170 may include an insulating material such as, for example, silicon carbonitride, silicon oxide, etc., and the first bonding pad 175 may include a metal such as, for example, copper.

The semiconductor chip stack units 500 stacked on the first semiconductor chip 100 may collectively form a semiconductor chip stack structure. FIG. 1 shows that each of the semiconductor chip stack units 500 includes two second semiconductor chips 200 stacked in the vertical direction, however, embodiments of the disclosure are not limited thereto, and each of the semiconductor chip stack units 500 may include more than two second semiconductor chips 200 stacked in the vertical direction.

Each of the second semiconductor chips 200 may include a second substrate 210 having a first surface 212 and a second surface 214 opposite to each other in the vertical direction, at least one second through electrode structure 220 extending through the second substrate 210, a third insulating interlayer and a fourth insulating interlayer 230 sequentially stacked in the vertical direction beneath the first surface 212 of the second substrate 210, a second bonding layer 240 beneath the fourth insulating interlayer 230, a second protective pattern structure 260 on the second surface 214 of the second substrate 210, and a third bonding layer 270 on the second protective pattern structure 260.

The second substrate 210 may include a semiconductor material such as, for example, silicon, germanium, silicon-germanium, or a III-V group compound semiconductor such as, for example, GaP, GaAs, GaSb, etc. In example embodiments, the second substrate 210 may be a silicon-on-insulator (SOI) substrate or a germanium-on-insulator (GOI) substrate.

A circuit device such as, for example, a volatile memory device (e.g., a DRAM device, an SRAM device, etc.), or a non-volatile memory device (e.g., a flash memory device, an EEPROM device, etc.), may be disposed beneath the first surface 212 of the second substrate 210. The circuit device may include circuit patterns, which may be covered by the third insulating interlayer.

The fourth insulating interlayer 230 may contain a second wiring structure 235 therein. The second wiring structure 235 may include, for example, wirings, vias, contact plugs, etc., and FIG. 1 shows only a single layer for the second wiring structure 235 in order to avoid complexity of the drawing.

The third insulating interlayer and the fourth insulating interlayer 230 may include, for example, silicon oxide or a low-k dielectric material such as, for example, an oxide doped with carbon or fluorine. The wirings, the vias, the contact plugs, etc., may include a conductive material such as, for example, a metal, a metal nitride, a metal silicide, etc.

The second bonding layer 240 may contain at least one second bonding pad 245 therein. In example embodiments, a plurality of second bonding pads 245 may be spaced apart from each other in the horizontal direction, and the second bonding pads 245 may contact a portion of the second wiring structure 235 to be electrically connected thereto.

In example embodiments, the second bonding layer 240 may include an insulating material such as, for example, silicon carbonitride, silicon oxide, etc., and the second bonding pad 245 may include a metal such as, for example, copper.

In example embodiments, a lower surface of a lowermost one of the second bonding layers 240 included in a lowermost one of the semiconductor chip stack units 500 may contact an upper surface of the first bonding layer 170 of the first semiconductor chip 100 so that a first bonding layer structure may be formed, and the second bonding pads 245 in the second bonding layer 240 may be bonded to the first bonding pads 175 in the first bonding layer 170 so that a first bonding pad structure may be formed.

The at least one second through electrode structure 220 may extend through the second substrate 210 in the vertical direction. A portion of the second through electrode structure 220 may protrude upwardly in the vertical direction, which may be referred to as a protrusion portion, and a sidewall of the protrusion portion of the second through electrode structure 220 may be covered by the second protective pattern structure 260. A plurality of second through electrode structures 220 may be spaced apart from each other in the horizontal direction. In example embodiments, the second through electrode structure 220 may include a second through electrode extending in the vertical direction, a second barrier pattern covering a sidewall of the second through electrode, and a second insulation pattern covering an outer sidewall of the second barrier pattern. However, in an example embodiment, the second insulation pattern may not cover an upper portion of the outer sidewall of the second barrier pattern.

The second through electrode may include a metal such as, for example, copper, aluminum, etc., the second barrier pattern may include a metal nitride such as, for example, titanium nitride, tantalum nitride, etc., and the second insulation pattern may include an oxide such as, for example, silicon oxide or an insulating nitride (e.g., silicon nitride).

In an example embodiment, the second through electrode structure 220 may extend through the second protective pattern structure 260, the second substrate 210, and the third insulating interlayer to contact the second wiring structure 235, and may be electrically connected to the second bonding pad 245 by the second wiring structure 235.

Alternatively, the second through electrode structure 220 may extend through the second protective pattern structure 260, the second substrate 210, the third insulating interlayer, and the fourth insulating interlayer 230 to contact the second bonding pad 245, and may be electrically connected thereto. Alternatively, the second through electrode structure 220 may extend through the second protective pattern structure 260 and the second substrate 210 to contact one of the circuit patterns included in the circuit device covered by the third insulating interlayer, and may be electrically connected to the second bonding pad 245 by the one of the circuit patterns and the second wiring structure 235.

The second protective pattern structure 260 may be disposed on the second surface 214 of the second substrate 210, and may surround the protrusion portion of the second through electrode structure 220. In an example embodiment, the second protective pattern structure 260 may contact an outer sidewall of an upper portion of the second barrier pattern of the second through electrode structure 220.

In example embodiments, the second protective pattern structure 260 may include a third protective pattern and a fourth protective pattern sequentially stacked in the vertical direction on the second surface 214 of the second substrate 210. A portion of the third protective pattern adjacent to the second through electrode structure 220 may protrude upwardly in the vertical direction, and an upper surface of the portion of the second protective pattern may be substantially coplanar with an upper surface of the second through electrode structure 220. An outer sidewall of the portion of the third protective pattern may be covered by the fourth protective pattern.

The third protective pattern may include an oxide such as, for example, silicon oxide, and the fourth protective pattern may include an insulating nitride such as, for example, silicon nitride.

The third bonding layer 270 may contain at least one third bonding pad 275 therein. In example embodiments, a plurality of third bonding pads 275 may be spaced apart from each other in the horizontal direction, and the third bonding pads 275 may contact upper surfaces of the second through electrode structures 220, respectively.

In example embodiments, the third bonding layer 270 may include an insulating material such as, for example, silicon carbonitride, silicon oxide, etc., and the third bonding pad 275 may include a metal such as, for example, copper.

In example embodiments, a lower surface of the second bonding layer 240 of an upper one of the second semiconductor chips 200 may contact an upper surface of the third bonding layer 270 of a lower one of the second semiconductor chips 200 so that a second bonding layer structure may be formed, and the second bonding pads 245 in the second bonding layer 240 may be bonded to the third bonding pads 275 in the third bonding layer 170 so that a second bonding pad structure may be formed.

In example embodiments, a first trench 800 may be formed at (e.g., defined by) a portion of the second substrate 210 adjacent to the second surface 214, that is, an upper portion of the second substrate 210 included in an uppermost one of the second semiconductor chips 200 in each of the semiconductor chip stack units 500, and a gap 810 may be formed between an upper surface of a portion of the third bonding layer 270 on the first trench 800 and a lower surface of the second bonding layer 240 included in a lowermost one of the second semiconductor chips 200 in one of the semiconductor chip stack units 500 that is disposed on each of the semiconductor chip stack units 500. Thus, the gap 810 may overlap the first trench 800 in the vertical direction. For example, the substrate 210 of the second semiconductor chip 200 may include at least one trench 800 that at least partially defines at least one gap 810. For example, at least a part of the at least one gap 810 may be defined due to the portion of the third bonding layer 270 being recessed in the at least one trench 800.

In an example embodiment, the gap 810 may extend in a first direction D1, which may be one of the horizontal directions, to a given length at each of opposite lateral portions of a semiconductor package in the first direction D1, and a plurality of gaps 810 may be spaced apart from each other in a second direction D2, which may be one of the horizontal directions and cross the first direction D1. Additionally, the gap 810 may extend in the second direction D2 to a given length at each of opposite lateral portions of the semiconductor package in the second direction D2, and a plurality of gaps 810 may be spaced apart from each other in the first direction D1. Thus, the gaps 810 may be arranged at edge portions of the semiconductor package in a ring shape in a plan view.

However, embodiments of the disclosure are not limited thereto, and the gaps 810 may be disposed only at opposite lateral portions of the semiconductor package in the first direction D1, or only at opposite lateral portions of the semiconductor package in the second direction D2. In some embodiments, the gap 810 may extend in the second direction D2 at each of opposite lateral portions of the semiconductor package in the first direction D1, or may extend in the first direction D1 at each of opposite lateral portions of the semiconductor package in the second direction D2.

The third semiconductor chip 300 may include a third substrate 310 having a first surface 312 and a second surface 314 opposite to each other in the vertical direction, a fifth insulating interlayer and a sixth insulating interlayer 330 sequentially stacked in the vertical direction beneath the first surface 312 of the third substrate 310, and a fourth bonding layer 340 beneath the sixth insulating interlayer 330.

A circuit device such as, for example, a volatile memory device or a non-volatile memory device may be disposed beneath the first surface 312 of the third substrate 310. The circuit device may include circuit patterns, which may be covered by the fifth insulating interlayer. The sixth insulating interlayer 330 may contain a third wiring structure 335 therein.

The fourth bonding layer 340 may contain at least one fourth bonding pad 345 therein. In example embodiments, a plurality of fourth bonding pads 345 may be spaced apart from each other in the horizontal direction, and the fourth bonding pads 345 may contact a portion of the third wiring structure 335 to be electrically connected thereto.

In example embodiments, the fourth bonding layer 340 may include an insulating material such as, for example, silicon carbonitride, silicon oxide, etc., and the fourth bonding pad 345 may include a metal such as, for example, copper.

In example embodiments, a lower surface of the fourth bonding layer 340 of the third semiconductor chip 300 may contact an upper surface of the third bonding layer 270 of an uppermost one of the second semiconductor chips 200 included in an uppermost one of the semiconductor chip stack units 500 so that a third bonding layer structure may be formed, and the fourth bonding pads 345 in the fourth bonding layer 340 may be bonded to the third bonding pads 275 in the third bonding layer 270 so that a third bonding pad structure may be formed.

In example embodiments, the first trench 800 may be formed at the portion of the second substrate 210 adjacent to the second surface 214, that is, the upper portion of the second substrate 210 included in the uppermost one of the second semiconductor chips 200 in an uppermost one of the semiconductor chip stack units 500, and the gap 810 may be formed between the upper surface of the portion of the third bonding layer 270 on the first trench 800 and a lower surface of the fourth bonding layer 340 of the third semiconductor chip 300.

The molding member 600 may cover sidewalls of the semiconductor chip stack structure and the third semiconductor chip 300, and an upper surface of the molding member 600 may be substantially coplanar with an upper surface of the third semiconductor chip 300. In example embodiments, the molding member 600 may fill the gap 810, and thus may contact the upper surface of the third bonding layer 270, the lower surface of the second bonding layer 240 and the lower surface of the fourth bonding layer 340.

The molding member 600 may include a polymer such as, for example, epoxy molding compound (EMC).

In the semiconductor package, the second semiconductor chips 200 stacked on the first semiconductor chip 100 may be bonded to each other by a hybrid copper bonding (HCB) process, as described below. That is, the second semiconductor chips 200 may be bonded to each other through the second bonding layer 240 and the third bonding layer 270 and the second bonding pads 245 and the third bonding pads 275.

During the HCB process, in a comparative embodiment, voids may be generated between the second semiconductor chips 200 to reduce the bonding force between the second semiconductor chips 200, and particularly, as the number of the second semiconductor chips 200 stacked in the vertical direction increases, more voids may be generated between upper ones of the second semiconductor chips 200.

However, in example embodiments, as the first trench 800 is formed on (e.g., defined by) some of the second semiconductor chips 200, that is, on (e.g., defined by) the uppermost one of the second semiconductor chips 200 in each of the semiconductor chip stack units 500, the gap 810 may be formed between the semiconductor chip stack units 500, and the voids generated during the HCB process may be efficiently emitted through the gap 810. Accordingly, even though a large number of second semiconductor chips 200 are stacked in the vertical direction and bonded to each other, the bonding force between the second semiconductor chips 200 may not be reduced due to the voids.

The first trench 800 may not be formed on each of the second semiconductor chips 200, but may be formed only on some of the second semiconductor chips 200, that is, only on the uppermost one of the second semiconductor chips 200 included in each of the semiconductor chip stack units 500. Thus, when compared to a case in which the first trench 800 is formed on each of the second semiconductor chips 200, the number of processes for forming the first trenches 800 may be reduced so that the cost for manufacturing the semiconductor package may be reduced.

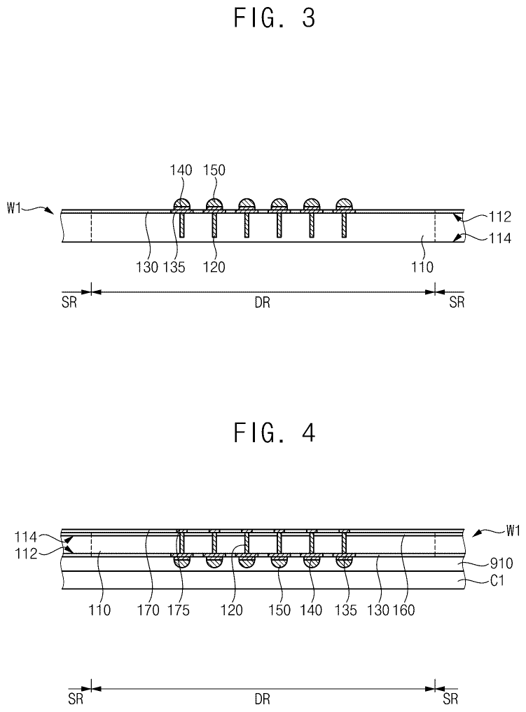

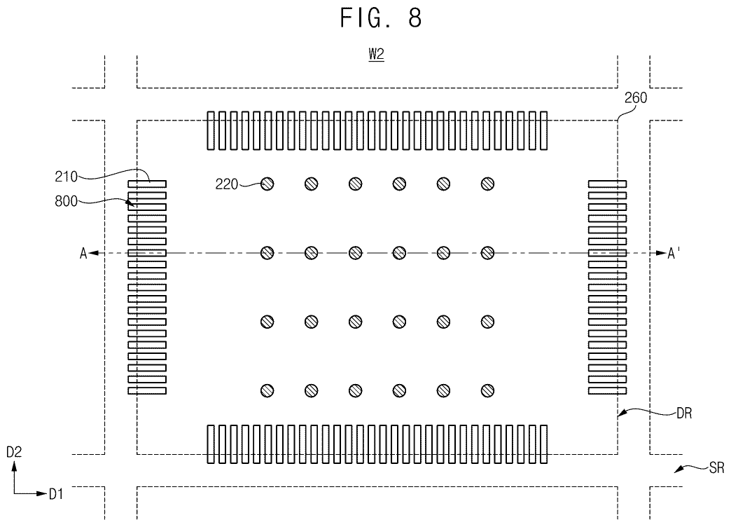

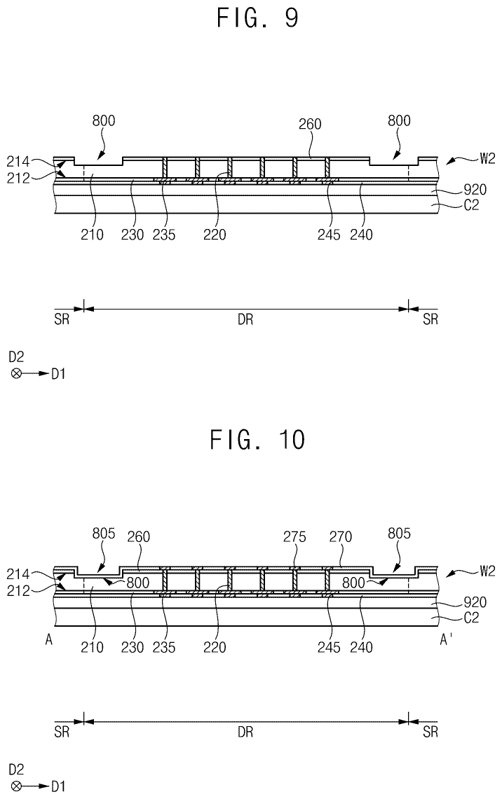

FIGS. 3 to 12 are cross-sectional views and a plan view illustrating a method of manufacturing a semiconductor package in accordance with example embodiments. Particularly, FIGS. 3-7 and 9-12 are the cross-sectional views, and FIG. 8 is the plan view. FIGS. 9 and 10 are cross-sectional views taken along a line A-A′ of FIG. 8.

Referring to FIG. 3, a first wafer W1 may be provided.

In example embodiments, the first wafer W1 may include a first substrate 110 having a first surface 112 and a second surface 114 opposite to each other in the vertical direction. Additionally, the first wafer W1 may include a plurality of die regions DR and a scribe lane region SR surrounding each of the die regions DR. The first wafer W1 may be cut along the scribe lane region SR by a sawing process to be singulated into a plurality of first semiconductor chips.

In the die region DR, a circuit device may be formed on the first surface 112 of the first substrate 110. The circuit device may include a logic device. The circuit device may include circuit patterns, and a first insulating interlayer may be formed on the first surface 112 of the first substrate 110 to cover the circuit patterns.

A second insulating interlayer 130 may be formed on the first insulating interlayer, and may contain a first wiring structure 135 therein.

At least one conductive pad 140 may be formed on second insulating interlayer 130 to contact the first wiring structure 135 to be electrically connected thereto.

In an example embodiment, the conductive pad 140 may be formed by following processes.

Particularly, a first seed layer may be formed on the second insulating interlayer 130, a first photoresist pattern including a first opening partially exposing an upper surface of the first seed layer may be formed on the first seed layer, and an electroplating process or an electroless plating process may be performed to form first and second conductive patterns in the first opening.

The first photoresist pattern may be removed by, for example, an ashing process and/or a stripping process to expose a portion of the first seed layer, the exposed portion of the first seed layer may be removed to form a first seed pattern under the first conductive pattern.

Thus, the conductive pad 140 including the first seed pattern and the first and second conductive patterns sequentially stacked in the vertical direction may be formed.

At least one first conductive connection member 150 may be formed on the at least one first conductive pad 140.

In an example embodiment, the first conductive connection member 150 may be formed by following processes.

Particularly, a second photoresist pattern including a second opening exposing an upper surface of the first conductive pad 140 may be formed on the second insulating interlayer 130, and an electroplating process or an electroless plating process may be performed to form a preliminary first conductive connection member in the second opening. After removing the second photoresist pattern, a reflow process may be performed so that the preliminary first conductive connection member may be transformed into a first conductive connection member 150.

In example embodiments, the first conductive connection member 150 may have, for example, a hemispherical shape or a semi-oval shape.

In example embodiments, at least one first through electrode structure 120 extending in the vertical direction through an upper portion of the first substrate 110, that is, a portion of the first substrate 110 adjacent to the first surface 112 thereof may be formed. In example embodiments, a plurality of first through electrode structures 120 may be spaced apart from each other in the horizontal direction in each of the die regions DR of the first wafer W1.

In an example embodiment, the first through electrode structure 120 may include a first through electrode extending in the vertical direction, a first barrier pattern covering a sidewall and a lower surface of the first through electrode, and a first insulation pattern covering a sidewall and a lower surface of the first barrier pattern.

Referring to FIG. 4, a first temporary bonding layer 910 may be attached to a first carrier substrate C1, and the first temporary bonding layer 910 may be bonded to an upper surface of the second insulating interlayer 130 including the first wiring structure 135 to cover the at least one first conductive connection member 150 and the at least one first conductive pad 140 on the first wafer W1 so that the first carrier substrate C1 may be bonded to the first wafer W1.

The first temporary bonding layer 910 may include a material losing adhesion by irradiation of light such as, for example, ultraviolet (UV) light or heat. In an example embodiment, the first temporary bonding layer 910 may include glue.

After flipping the first wafer W1, a portion of the first substrate 110 adjacent to the second surface 114 of the first substrate 110 may be removed by, for example, a grinding process to expose an upper portion of the at least one first through electrode structure 120.

In an example embodiment, an upper portion of the first insulation pattern of the first through electrode structure 120 may also be removed by the grinding process, and thus an upper surface and an upper outer sidewall of the first barrier pattern may be exposed.

A first protective layer structure may be formed on the second surface 114 of the first substrate 110 to cover the first through electrode structure 120, and a planarization process may be performed on the first protective layer structure until an upper surface of the first through electrode of the first through electrode structure 120 is exposed to form a first protective pattern structure 160.

In example embodiments, the planarization process may include a chemical mechanical polishing (CMP) process and/or an etch back process.

In example embodiments, the first protective layer structure may include first to third protective layers sequentially stacked in the vertical direction, and during the planarization process, the third protective layer may be removed and the second protective layer may partially remain. Thus, the first protective pattern structure 160 may include first and second protective patterns sequentially stacked in the vertical direction. An upper outer sidewall of a portion of the first protective pattern adjacent to the first through electrode structure 120 may be covered by the second protective pattern.

A first bonding layer 170 including at least one first bonding pad 175 therein may be formed on the first protective pattern structure 160 and the at least one first through electrode structure 120.

In example embodiments, a plurality of first bonding pads 175 may be spaced apart from each other in the horizontal direction, and may contact upper surfaces of the first through electrode structures 120, respectively.

In example embodiments, the first bonding layer 170 may include an insulating material such as, for example, silicon carbonitride, silicon oxide, etc., and the first bonding pad 175 may include a metal such as, for example, copper.

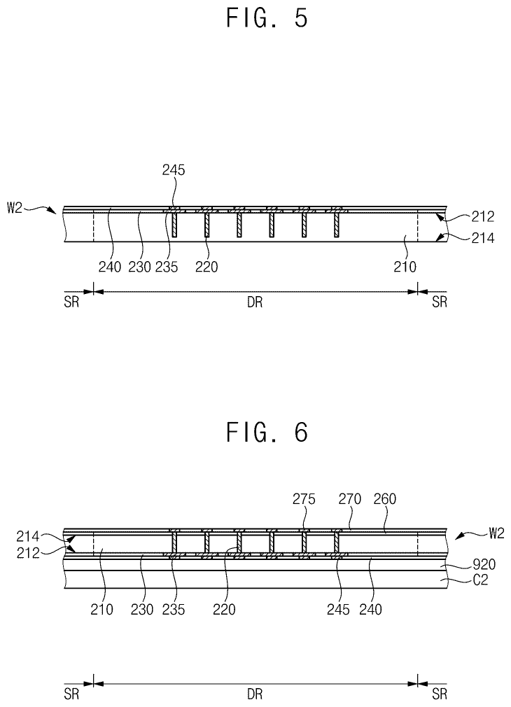

Referring to FIG. 5, a second wafer W2 may be provided.

In example embodiments, the second wafer W2 may include a second substrate 210 having a first surface 212 and a second surface 214 opposite to each other in the vertical direction. Additionally, the second wafer W2 may include a plurality of die regions DR and a scribe lane region SR surrounding each of the die regions DR. The second wafer W2 may be cut along the scribe lane region SR by a sawing process to be singulated into a plurality of second semiconductor chips.

In the die region DR, a circuit device may be formed on the first surface 212 of the second substrate 210. The circuit device may include a memory device. The circuit device may include circuit patterns, and a third insulating interlayer may be formed on the first surface 212 of the second substrate 210 to cover the circuit patterns.

A fourth insulating interlayer 230 may be formed on the third insulating interlayer, and may contain a second wiring structure 235 therein.

In example embodiments, at least one second through electrode structure 220 extending in the vertical direction through an upper portion of the second substrate 210, that is, a portion of the second substrate 210 adjacent to the first surface 212 thereof may be formed. In example embodiments, a plurality of second through electrode structures 220 may be spaced apart from each other in the horizontal direction in each of the die regions DR of the second wafer W2.

In an example embodiment, the second through electrode structure 220 may include a second through electrode extending in the vertical direction, a second barrier pattern covering a sidewall and a lower surface of the second through electrode, and a second insulation pattern covering a sidewall and a lower surface of the second barrier pattern.

A second bonding layer 240 including at least one second bonding pad 245 therein may be formed on the fourth insulating interlayer 230 including the second wiring structure 235.

In example embodiments, a plurality of second bonding pads 245 may be spaced apart from each other in the horizontal direction, and some of the second bonding pads 245 may contact an upper surface of the second wiring structure 235.

In example embodiments, the second bonding layer 240 may include an insulating material such as, for example, silicon carbonitride, silicon oxide, etc., and the second bonding pad 245 may include a metal such as, for example, copper.

Referring to FIG. 6, a second temporary bonding layer 920 may be attached to a second carrier substrate C2, and the second temporary bonding layer 920 may be bonded to an upper surface of the second bonding layer 240 including the at least one second bonding pad 245 on the second wafer W2 so that the second carrier substrate C2 may be bonded to the second wafer W2.

The second temporary bonding layer 920 may include a material losing adhesion by irradiation of light such as, for example, UV light or heat. In an example embodiment, the second temporary bonding layer 920 may include glue.

After flipping the second wafer W2, a portion of the second substrate 210 adjacent to the second surface 214 of the second substrate 210 may be removed by, for example, a grinding process to expose an upper portion of the at least one second through electrode structure 220.

In an example embodiment, during the grinding process, an upper portion of the second insulation pattern included in the second through electrode structure 220 may also be removed, so that an upper surface and an upper outer sidewall of the second barrier pattern may be exposed.

A second protective layer structure may be formed on the second surface 214 of the second substrate 210 to cover the at least one second through electrode structure 220, and a planarization process may be performed on the second protective layer structure until an upper surface of the second through electrode of the second through electrode structure 220 is exposed to form a second protective pattern structure 260.

In example embodiments, the first protective layer structure may include fourth to sixth protective layers sequentially stacked in the vertical direction, and during the planarization process, the sixth protective layer may be removed and the fifth protective layer may partially remain. Thus, the second protective pattern structure 260 may include fourth and fifth protective patterns sequentially stacked in the vertical direction. An upper outer sidewall of a portion of the fourth protective pattern adjacent to the second through electrode structure 220 may be covered by the fifth protective pattern.

A third bonding layer 270 including at least one third bonding pad 275 therein may be formed on the second protective pattern structure 260 and the at least one second through electrode structure 220.

In example embodiments, a plurality of third bonding pads 275 may be spaced apart from each other in the horizontal direction, and may contact upper surfaces of the second through electrode structures 220, respectively.

In example embodiments, the third bonding layer 270 may include an insulating material such as, for example, silicon carbonitride, silicon oxide, etc., and the third bonding pad 275 may include a metal such as, for example, copper.

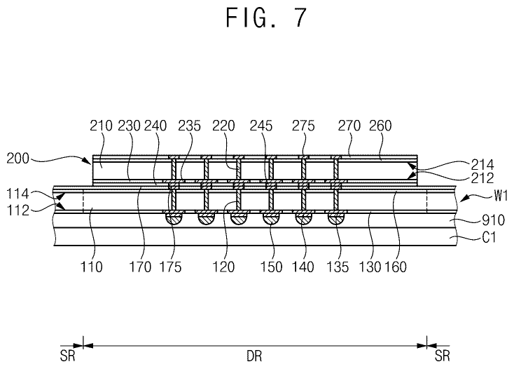

Referring to FIG. 7, after flipping the second wafer W2, the second wafer W2 may be attached to an upper surface of a release tape on a frame having a shape of, for example, a ring.

The release tape may contact an upper surface of the third bonding layer 270 on the second surface 214 of the second wafer W2.

The second temporary bonding layer 920 attached to the second carrier substrate C2 may be separated from the second bonding layer 240, so that the second carrier substrate C2 may be separated from the second wafer W2.

After cutting the wafer W2 along the scribe lane region SR by a sawing process into second semiconductor chips 200, each of the second semiconductor chips 200 may be separated from the release tape, and may be mounted on the first wafer W1 such that the second bonding layer 240 of the second semiconductor chip 200 may contact an upper surface of the first bonding layer 170 of the first wafer W1.

Each of the second semiconductor chips 200 may be mounted on a corresponding one of the die regions DR of the first wafer W1, and the second bonding pad 245 of the second semiconductor chip 200 may contact an upper surface of the bonding pad 175 of the first semiconductor chip. The first bonding layer 170 and the second bonding layer 240 may be bonded to each other to form a first bonding layer structure, and the first bonding pads 175 and the second bonding pads 245 may be bonded to each other to form a first bonding pad structure. That is, each of the second semiconductor chips 200 may be bonded to the first wafer W1 by a hybrid copper bonding (HCB) process.

Referring to FIGS. 8 and 9, processes substantially the same as or similar to those illustrated with respect to FIGS. 5 and 6 may be performed.

Particularly, the second wafer W2 including the second substrate 210 having the first surface 212 and the second surface 214 opposite to each other in the vertical direction may be provided. The at least one second through electrode structure 220 may extend in the vertical direction through the second substrate 210. The third insulating interlayer and the fourth insulating interlayer 230 including the second wiring structure 235 may be formed on the first surface 212 of the second substrate 210. The second bonding layer 240 including the at least one second bonding pad 245 may be formed on the fourth insulating interlayer 230.

The second temporary bonding layer 920 may be attached to the second carrier substrate C2, and the second temporary bonding layer 920 may be bonded to the upper surface of the second bonding layer 240 on the second wafer W2 so that the second carrier substrate C2 may be bonded to the second wafer W2. After flipping the second wafer W2, the portion of the second substrate 210 adjacent to the second surface 214 of the second substrate 210 may be removed by, for example, a grinding process to expose the upper portion of the second through electrode structure 220.

The second protective layer structure may be formed on the second surface 214 of the second substrate 210 to cover the at least one second through electrode structure 220, and the planarization process may be performed on the second protective layer structure until the upper surface of the second through electrode of the second through electrode structure 220 is exposed to form the second protective pattern structure 260.

The second protective pattern structure 260 and a portion of the second substrate 210 adjacent to the second surface 214 may be partially removed to form a first trench 800.

In example embodiments, the first trench 800 may be formed at an edge portion of each of the die regions DR and a portion of the scribe lane region SR adjacent to the die regions DR.

In an example embodiment, the first trench 800 may extend in the first direction D1 to a given length at each of opposite lateral portions in the first direction D1 of each of the die regions DR and a portion of the scribe lane region SR adjacent to the die regions DR in the first direction D1, and a plurality of first trenches 800 may be formed to be spaced apart from each other in the second direction D2. Additionally, the first trench 800 may extend in the second direction D2 to a given length at each of opposite lateral portions in the second direction D2 of each of the die regions DR and a portion of the scribe lane region SR adjacent to the die regions DR in the second direction D2, and a plurality of first trenches 800 may be formed to be spaced apart from each other in the first direction D1.

However, embodiments of the disclosure are not limited thereto, and in some embodiments, the first trench 800 may be formed only at each of opposite lateral portions in the first direction D1, or only at each of opposite lateral portions in the second direction D2. Additionally, the first trench 800 may extend in the second direction D2 at each of opposite lateral portions in the first direction D1, or may extend in the first direction D1 at each of opposite lateral portions in the second direction D2.

Referring to FIG. 10, a third bonding layer 270 including at least one third bonding pad 275 therein may be formed on the second surface 214 of the second substrate 210, an inner wall of the first trench 800 and an upper surface of the second protective pattern structure 260.

In example embodiments, the third bonding layer 270 may be conformally formed, and thus a second trench 805 may be formed on an upper surface of a portion of the third bonding layer 270 in the first trench 800.

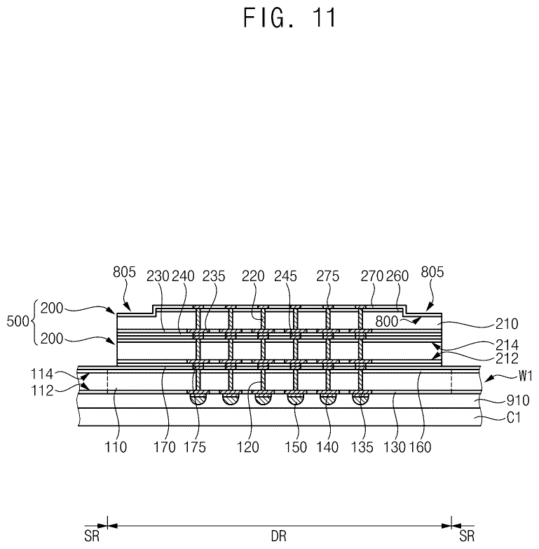

Referring to FIG. 11, processes similar to those illustrated with respect to FIG. 7 may be performed.

Thus, a second carrier substrate C2 may be separated from a second wafer W2, the second wafer W2 may be cut along the scribe lane region SR by a sawing process into second semiconductor chips 200, and each of the second semiconductor chips 200 may be mounted on a corresponding one of the second semiconductor chips 200 that are stacked on the first wafer W1 such that the second bonding layer 240 of each of the second semiconductor chips 200 may contact an upper surface of the third bonding layer 270 of the corresponding one of the second semiconductor chips 200 on the first wafer W1.

The second bonding layer 240 of each of the second semiconductor chips 200 may be bonded to the third bonding layer 270 of the corresponding one of the second semiconductor chips 200 on the first wafer W1 to form a second bonding layer structure, and the second bonding pads 245 and the third bonding pads 275 in the second bonding layer 240 and the third bonding layer 270, respectively, may be bonded to each other to form a second bonding pad structure. That is, the second semiconductor chips 200 may be bonded to each other by an HCB process.

The second semiconductor chips 200 stacked in the vertical direction may collectively form a semiconductor chip stack unit 500, and the second trench 805 may be formed at an upper surface of each of edge portions of the semiconductor chip stack unit 500.

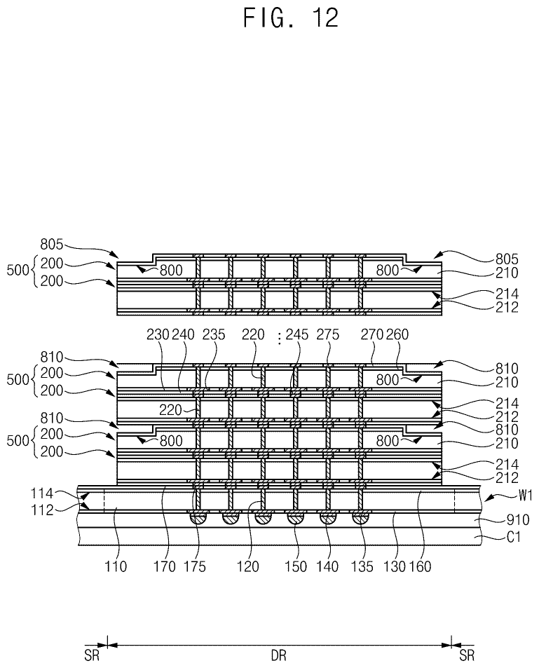

Referring to FIG. 12, additional semiconductor chip stack units 500 may be stacked on the semiconductor chip stack unit 500 on the first wafer W1 by an HCB process.

A gap 810 may be formed between an upper surface of a portion of a lower one of the semiconductor chip stack units 500 on which the second trench 805 is formed and a lower surface of a portion of an upper one of the semiconductor chip stack units 500 corresponding to the portion of the lower one of the semiconductor chip stack units 500.

Referring back to FIGS. 1 and 2, a third semiconductor chip 300 may be bonded to an upper surface of an uppermost one of the semiconductor chip stack units 500 by an HCB process.

The third semiconductor chip 300 may include a third substrate 310 having a first surface 312 and a second surface 314 opposite to each other in the vertical direction.

A circuit device may be formed on the first surface 312 of the third substrate 310, and a fifth insulating interlayer covering the circuit device and a fourth insulating interlayer 230 including a third wiring structure 335 therein may be formed beneath the first surface 312 of the third substrate 310. A fourth bonding layer 340 including at least one fourth bonding pad 345 may be formed beneath the sixth insulating interlayer 330.

The fourth bonding layer 340 of the third semiconductor chip 300 may be bonded to the third bonding layer 270 of the second semiconductor chip 200 to form a third bonding layer structure, and the third bonding pads 275 and fourth bonding pads 345 in the third bonding layer 270 and the fourth bonding layer 240, respectively, may be bonded to each other to form a third bonding pad structure.

The gap 810 may be formed between the upper surface of the portion of the semiconductor chip stack unit 500 on which the second trench 805 is formed and a lower surface of a portion of the third semiconductor chip 300 corresponding to the portion of the semiconductor chip stack unit 500.

A molding member 600 may be formed on the first wafer W1 to cover the semiconductor chip stack units 500 and the third semiconductor chip 300.

In example embodiments, the molding member 600 may expose an upper surface of the third semiconductor chip 300, and may fill the gaps 810.

The first wafer W1 may be cut along the scribe lane region SR by, for example, a sawing process to be singulated into a plurality of first semiconductor chips 100.

During the sawing process, the molding member 600 may also be cut to cover sidewalls of the semiconductor chip stack units 500 and the third semiconductor chip 300.

The first temporary bonding layer 910 and the first carrier substrate C1 may be separated from each of the first semiconductor chips 100 to complete the manufacturing the semiconductor package.

As described above, the upper portion of the second wafer W2 may be removed to form the first trench 800, the third bonding layer 270 may be conformally formed on the second surface 214 of the second substrate 210 included in the second wafer W2, the inner wall of the first trench 800 and the upper surface of the second protective pattern structure 260 to form the second trench 805 on the portion of the third bonding layer 270 in the first trench 800, and one of the second semiconductor chips 200 having no second trench 805 may be stacked on and bonded to another of the second semiconductor chips 200 having the second trench 805 by an HCB process to form the semiconductor chip stack unit 500.

A plurality of semiconductor chip stack units 500 may be stacked in the vertical direction and bonded to each other by an HCB process, and the gap 810 may be formed between the semiconductor chip stack units 500.

If the first trench 800 is not formed on the second wafer W2 so that no second trench 805 is formed on the second semiconductor chip 200, when the second semiconductor chips 200 are stacked in the vertical direction and bonded to each other by an HCB process, voids may be generated between the second semiconductor chips 200, which may decrease the bonding force therebetween. Particularly, in a comparative embodiment, as the number of the second semiconductor chips 200 stacked in the vertical direction increases, more voids may be generated between the second semiconductor chips.

However, in example embodiments, the second trench 805 may be formed on some of the second semiconductor chips 200, that is, an uppermost one of each of the semiconductor chip stack units 500, so that the gap 810 may be formed between the semiconductor chip stack units 500, and the voids generated by the HCB process for bonding the semiconductor chip stack units 500 may be efficiently emitted outwardly. Accordingly, even though a large number of second semiconductor chips 200 are stacked in the vertical direction, the reduction of the bonding force between the semiconductor chip stack units 500 due to the voids may be prevented.

If the first trench 800 is formed on all of the second semiconductor chips 200 in order to remove the voids, the cost for forming the first trench 800 may increase.

However, in example embodiments, the first trench 800 or the second trench 805 may not be formed on all of the second semiconductor chips 200 but on each of the semiconductor chip stack units 500 each of which may include, for example, two second semiconductor chips 200, and thus the cost for forming the first trench 800 may be reduced.

FIG. 1 shows that each of the semiconductor chip stack units 500 includes two second semiconductor chips 200 stacked in the vertical direction. However, embodiments of the disclosure are not limited thereto, and each of the semiconductor chip stack units 500 may include more than two second semiconductor chips 200, which may decrease the cost for forming the first trench 800.

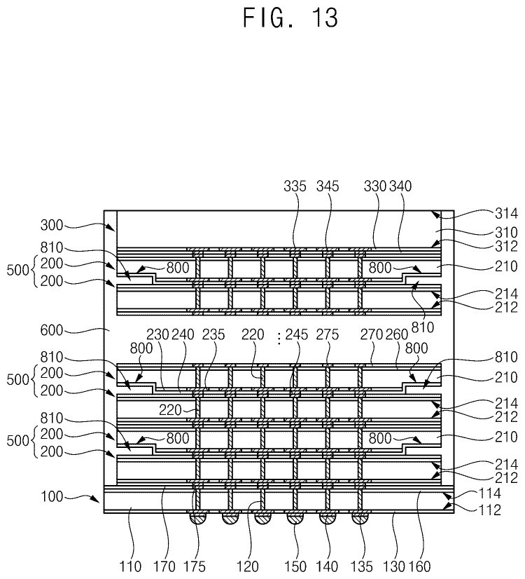

FIGS. 13 to 17 are cross-sectional views illustrating semiconductor packages in accordance with example embodiments, which may correspond to FIG. 2. These semiconductor packages may be substantially the same as or similar to the semiconductor package of FIGS. 1 and 2, except for positions of the first trench and the gap, and thus repeated explanations may be omitted herein.

Referring to FIG. 13, the first trench 800 may be formed on (e.g., defined by) a portion of the second substrate 210 adjacent to the first surface 212, that is, a lower portion of the second substrate 210 of an uppermost one of the second semiconductor chips 200 included in each of the semiconductor chip stack units 500, and the gap 810 may be formed between a lower surface of a portion of the second bonding layer 240 on the first trench 800 of the uppermost one of the second semiconductor chips 200 in each of the semiconductor chip stack units 500 and an upper surface of a portion of the third bonding layer 270 of one of the second semiconductor chips 200 directly under the uppermost one of the second semiconductor chips 200 in each of the semiconductor chip stack units 500. For example, the substrate 210 of the second semiconductor chip 200 may include at least one trench 800 that at least partially defines at least one gap 810. For example, at least a part of the at least one gap 810 may be defined due to the portion of the second bonding layer 240 being recessed in the at least one trench 800.

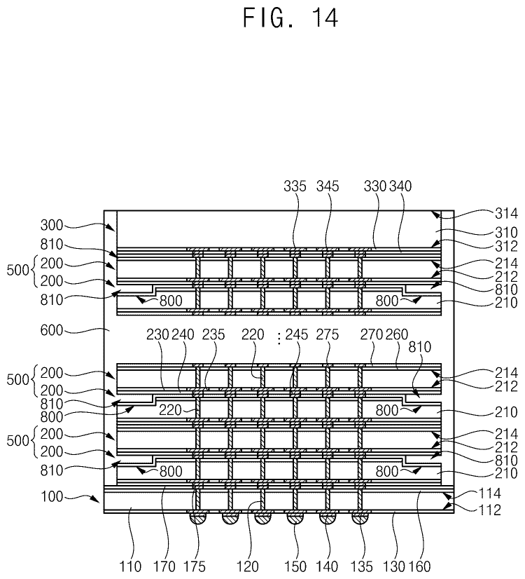

Referring to FIG. 14, the first trench 800 may be formed on a portion of the second substrate 210 adjacent to the second surface 214, that is, an upper portion of the second substrate 210 of a lowermost one of the second semiconductor chips 200 included in each of the semiconductor chip stack units 500, and the gap 810 may be formed between an upper surface of a portion of the third bonding layer 270 on the first trench 800 of the lowermost one of the second semiconductor chips 200 in each of the semiconductor chip stack units 500 and a lower surface of a portion of the second bonding layer 240 of one of the second semiconductor chips 200 directly over the lowermost one of the second semiconductor chips 200 in each of the semiconductor chip stack units 500.

If each of the semiconductor chip stack units 500 includes more than two second semiconductor chips 200, the first trench 800 may be formed on a portion of the second substrate 210 adjacent to the second surface 214, that is, an upper portion of the second substrate 210 of a middle one of the second semiconductor chips 200 included in each of the semiconductor chip stack units 500, and the gap 810 may be formed between an upper surface of a portion of the third bonding layer 270 on the first trench 800 of the middle one of the second semiconductor chips 200 in each of the semiconductor chip stack units 500 and a lower surface of a portion of the second bonding layer 240 of one of the second semiconductor chips 200 directly over the middle one of the second semiconductor chips 200 in each of the semiconductor chip stack units 500.

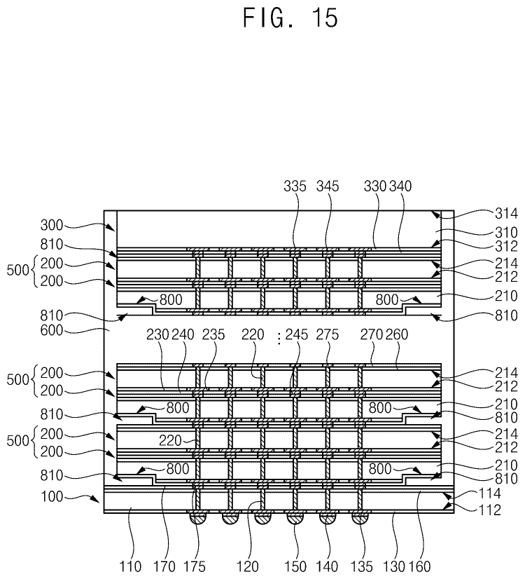

Referring to FIG. 15, the first trench 800 may be formed on a portion of the second substrate 210 adjacent to the first surface 212, that is, a lower portion of the second substrate 210 of a lowermost one of the second semiconductor chips 200 included in each of the semiconductor chip stack units 500, and the gap 810 may be formed between a lower surface of a portion of the second bonding layer 240 on the first trench 800 of the lowermost one of the second semiconductor chips 200 in each of the semiconductor chip stack units 500 and an upper surface of a portion of the third bonding layer 270 of an uppermost one of the second semiconductor chips 200 in a corresponding one of the semiconductor chip stack units 500 directly under each of the semiconductor chip stack units 500.

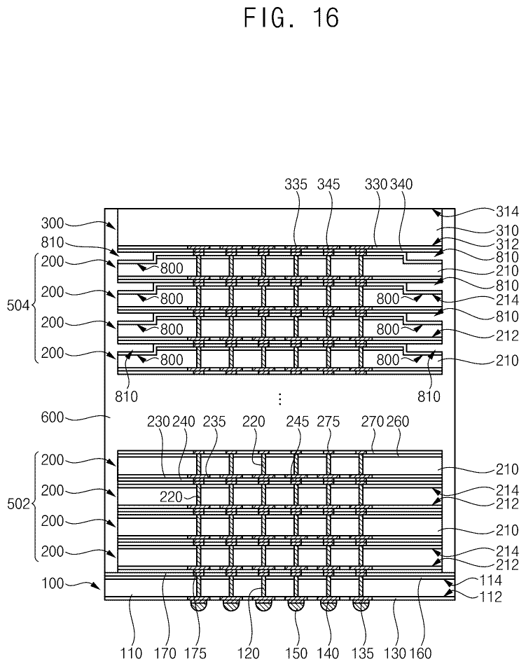

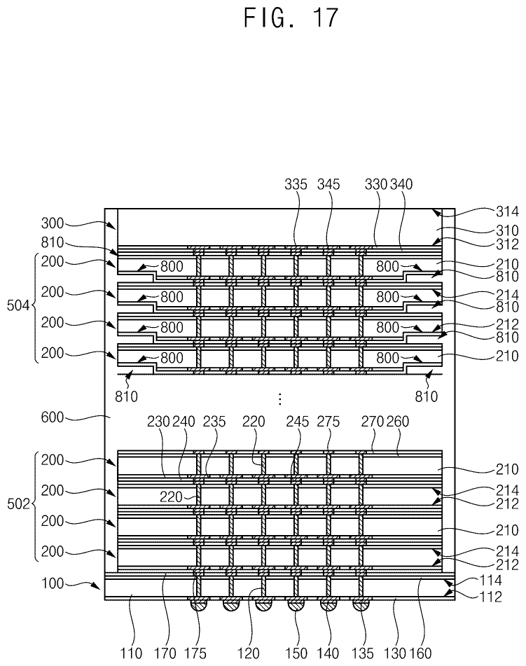

Referring to FIG. 16, the semiconductor chip stack structure may include first semiconductor chip stack units 502 and second semiconductor chip stack units 504 stacked in the vertical direction, and the first trench 800 may be formed on a portion of the second substrate 210 adjacent to the second surface 214, that is, an upper portion of the second substrate 210 of each of the second semiconductor chips 200 included in each of the second semiconductor chip stack units 504, and the gap 810 may be formed between an upper surface of a portion of the third bonding layer 270 on the first trench 800 of each of the second semiconductor chips 200 and a lower surface of a portion of the second bonding layer 240 of one of the second semiconductor chips 200 directly over each of the second semiconductor chips 200.

FIG. 16 shows that each of the first semiconductor chip stack units 502 and the second semiconductor chip stack units 504 includes four second semiconductor chips 200 stacked in the vertical direction, however, the inventive concept is not limited thereto, and each of the first semiconductor chip stack units 502 and the second semiconductor chip stack units 504 may include more or less than four second semiconductor chips 200.

In some embodiments, the first semiconductor chip stack units 502 and the second semiconductor chip stack units 504 may be alternately and repeatedly stacked in the vertical direction.

Referring to FIG. 17, the semiconductor chip stack structure may include first semiconductor chip stack units 502 and second semiconductor chip stack units 504 stacked in the vertical direction, and the first trench 800 may be formed on a portion of the second substrate 210 adjacent to the first surface 212, that is, a lower portion of the second substrate 210 of each of the second semiconductor chips 200 included in each of the second semiconductor chip stack units 504, and the gap 810 may be formed between a lower surface of a portion of the second bonding layer 240 on the first trench 800 of each of the second semiconductor chips 200 and an upper surface of a portion of the third bonding layer 270 of one of the second semiconductor chips 200 directly under each of the second semiconductor chips 200.

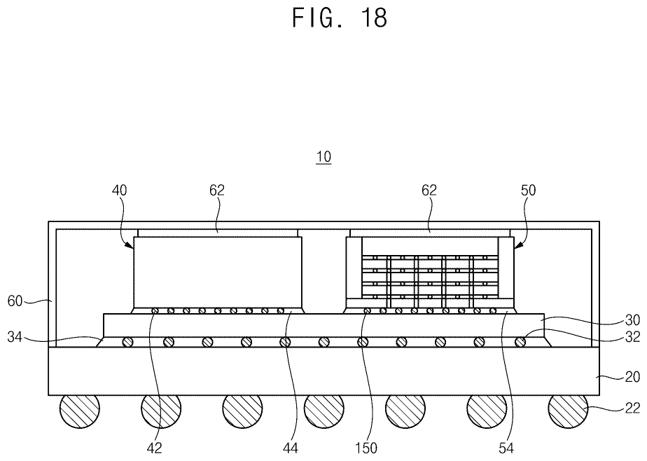

FIG. 18 is a cross-sectional view illustrating an electronic device in accordance with example embodiments.

This electronic device may include the semiconductor package shown in FIGS. 1 and 2 as a second semiconductor device 50. However, embodiments of the disclosure are not limited thereto, and for example, the electronic device may include one of the semiconductor packages shown in FIGS. 13 to 17 as the second semiconductor device 50.

Referring to FIG. 18, an electronic device 10 may include a package substrate 20, an interposer 30, a first semiconductor device 40 and the second semiconductor device 50. The electronic device 10 may further include a first underfill member 34, a second underfill member 44, a third underfill member 54, a heat slug 60, and a heat dissipation member 62.

In example embodiments, the electronic device 10 may be a memory module having a 2.5 dimensional (2.5D) package structure, and thus may include the interposer 30 for electrically connecting the first semiconductor device 40 and the second semiconductor device 50 to each other.

In example embodiments, the first semiconductor device 40 may include a logic device, and the second semiconductor device 50 may include a memory device. The logic device may be an application-specific integrated circuit (ASIC) chip including, for example, a central processing unit (CPU), a graphics processing unit (GPU), a micro-processor, a micro-controller, an application processor (AP), a digital signal processing core, etc. The memory device may be a semiconductor package such as an HBM package.

In example embodiments, the package substrate 20 may have an upper surface and a lower surface opposite to each other in the vertical direction. For example, the package substrate 20 may be a printed circuit board (PCB). The printed circuit board may be a multi-layer circuit board having various circuits therein.

The interposer 30 may be mounted on the package substrate 20 through at least one third conductive connection member 32. In example embodiments, a planar area of the interposer 30 may be smaller than a planar area of the package substrate 20. The interposer 30 may be disposed within an area of the package substrate 20 in a plan view.

The interposer 30 may be a silicon interposer or a redistribution interposer having a plurality of wirings therein. The first semiconductor device 40 and the second semiconductor device 50 may be connected to each other through the wirings in the interposer 30 or electrically connected to the package substrate 20 through the at least one third conductive connection member 32. The third conductive connection member 32 may include, for example, a micro-bump. The silicon interposer may provide a high-density interconnection between the first semiconductor device 40 and the second semiconductor device 50.

The first semiconductor device 40 may be disposed on the interposer 30. The first semiconductor device 40 may be mounted on and bonded to the interposer 30 by a flip chip bonding process. In this case, the first semiconductor device 40 may be mounted on the interposer 30 such that an active surface on which conductive pads are formed may face downwardly toward the interposer 30. The conductive pads of the first semiconductor device 40 may be electrically connected to conductive pads of the interposer 30 through at least one eighth conductive connection member 42. For example, the eighth conductive connection member 42 may include, for example, a micro-bump.

Alternatively, the first semiconductor device 40 may be mounted on the interposer 30 by a wire bonding process, and in this case, the active surface of the first semiconductor device 40 may face upwardly.

The second semiconductor device 50 may be disposed on the interposer 30, and may be spaced apart from the first semiconductor device 40 in the horizontal direction. The second semiconductor device 50 may be mounted on and bonded to the interposer 30 by, for example, a flip chip bonding process. In this case, conductive pads of the second semiconductor device 50 may be electrically connected to conductive pads of the interposer 30 by the first conductive connection member 150.

Although a single first semiconductor device 40 and a single second semiconductor device 50 are shown in FIG. 18 to be disposed on the interposer 30, embodiments of the disclosure are not limited thereto, and a plurality of first semiconductor devices 40 and/or a plurality of second conductive devices 50 may be disposed on the interposer 30.

In example embodiments, the first underfill member 34 may fill a space between the interposer 30 and the package substrate 20, and the second underfill member 44 and the third underfill member 54 may fill a space between the first semiconductor device 40 and the interposer 30 and a space between the second semiconductor device 50 and the interposer 30, respectively.

The first underfill member 34, the second underfill member 44, and the third underfill member 54 may include a material having a relatively high fluidity to effectively fill a small space between the first and second semiconductor devices 40 and 50 and the interposer 30 and a small space between the interposer 30 and the package substrate 20. For example, each of the first underfill member 34, the second underfill member 44, and the third underfill member 54 may include an adhesive containing an epoxy material.

The semiconductor device 50 may include a buffer die and a plurality of memory dies sequentially stacked on the buffer die. The buffer die and the memory dies may be electrically connected to each other by through electrodes such as, for example, through-silicon vias (TSVs), and the through electrodes may be electrically connected to each other by conductive connection members. Data signals and control signals may be transferred to the buffer die and the memory dies by the through electrodes.

In example embodiments, the heat slug 60 may be formed on the package substrate 20 to thermally contact the first semiconductor device 40 and the second semiconductor device 50. The heat dissipation member 62 may be disposed on an upper surface of each of the first semiconductor device 40 and the second semiconductor device 50, and may include, for example, thermal interface material (TIM). The heat slug 60 may thermally contact the first semiconductor device 40 and the second semiconductor device 50 via the heat dissipation member 62.

At least one conductive pad may be formed at a lower portion of the package substrate 20, and at least one second conductive connection member 22 may be disposed beneath the at least one conductive pad. In example embodiments, a plurality of second conductive connection members 22 may be spaced apart from each other in the horizontal direction. The second conductive connection member 22 may be, for example, a solder ball. The electronic device 10 may be mounted on a module board via the sixth conductive connection members 22 to form a memory module.

Non-limiting example embodiments of the disclosure have been described above with reference to the accompanying drawings. However, the disclosure is not limited to the example embodiments. Those skilled in the art will readily appreciate that many modifications are possible in example embodiments without departing from the spirit and scope of the disclosure. Accordingly, all such modifications are intended to be included within the scope of the disclosure.

What is claimed is:

1. A semiconductor package comprising:
a buffer die;
memory die stack units stacked in a vertical direction on the buffer die, each of the memory die stack units comprising memory dies stacked in the vertical direction; and
a molding member on the buffer die, the molding member covering sidewalls of the memory die stack units,
wherein at least one gap is between a first memory die, from among the memory dies of the memory die stack units, and a second memory die, from among the memory dies of the memory die stack units, the second memory die being over or under the first memory die in the vertical direction,
wherein the first memory die includes at least one trench that at least partially defines the at least one gap, and
wherein the molding member is in the at least one gap.

2. The semiconductor package according to claim 1, wherein the first memory die is an uppermost memory die of one of the memory die stack units, and the second memory die is over the first memory die, and
wherein the at least one gap is between an upper surface of the first memory die and a lower surface of the second memory die.

3. The semiconductor package according to claim 1, wherein the first memory die is an uppermost memory die of one of the memory die stack units, and the second memory die is under the first memory die, and
wherein the at least one gap is between a lower surface of the first memory die and an upper surface of the second memory die.

4. The semiconductor package according to claim 1, wherein the first memory die is a lowermost memory die of one of the memory die stack units, and the second memory die is over the first memory die, and
wherein the at least one gap is between an upper surface of the first memory die and a lower surface of the second memory die.

5. The semiconductor package according to claim 1, wherein the first memory die is a lowermost memory die of one of the memory die stack units, and the second memory die is under the first memory die, and
wherein the at least one gap is between a lower surface of the first memory die and an upper surface of the second memory die.

6. The semiconductor package according to claim 1, wherein each of the memory die stack units comprises a same number of the memory dies.

7. The semiconductor package according to claim 1, wherein each of the memory dies comprises:
a substrate;
a first bonding layer on a lower surface of the substrate, the first bonding layer comprising a first bonding pad; and
a second bonding layer on an upper surface of the substrate, the second bonding layer comprising a second bonding pad,
wherein the at least one gap is between an upper surface of the second bonding layer of the first memory die and a lower surface of the first bonding layer of the second memory die.

8. The semiconductor package according to claim 7, wherein each of the first bonding layer and the second bonding layer comprises silicon carbonitride or silicon oxide, and
wherein each of the first bonding pad and the second bonding pad comprises copper.

9. The semiconductor package according to claim 1, wherein each of the memory dies comprises:
a substrate;
a first bonding layer on a lower surface of the substrate, the first bonding layer comprising a first bonding pad; and
a second bonding layer on an upper surface of the substrate, the second bonding layer comprising a second bonding pad,
wherein the at least one gap is between a lower surface of the first bonding layer of the first memory die and an upper surface of the second bonding layer of the second memory die.

10. The semiconductor package according to claim 9, wherein each of the first bonding layer and the second bonding layer comprises silicon carbonitride or silicon oxide, and
wherein each of the first bonding pad and the second bonding pad comprises copper.

11. The semiconductor package according to claim 1, wherein the at least one gap is a plurality of gaps, and
wherein the plurality of gaps are arranged in a ring shape at edge portions of the first memory die in a plan view.

12. A semiconductor package comprising:
a buffer die;
a first memory die stack unit comprising first memory dies stacked in a vertical direction on the buffer die;
a second memory die stack unit comprising second memory dies stacked in the vertical direction on the first memory die stack unit; and
a molding member on the buffer die, the molding member covering a sidewall of the first memory die stack unit and a sidewall of the second memory die stack unit,
wherein at least one gap is between the second memory dies,
wherein at least one of the second memory dies includes at least one trench that at least partially defines the at least one gap, and
wherein the molding member is in the at least one gap.

13. The semiconductor package according to claim 12, wherein each of the second memory dies comprises:
a substrate;
a first bonding layer on a lower surface of the substrate, the first bonding layer comprising a first bonding pad; and
a second bonding layer on an upper surface of the substrate, the second bonding layer comprising a second bonding pad,
wherein the at least one gap is between an upper surface of the second bonding layer of one of the second memory dies and a lower surface of the first bonding layer of another one of the second memory dies, the another one of the second memory dies being above the one of the second memory dies.

14. The semiconductor package according to claim 13, wherein the at least one trench is a plurality of trenches, and the at least one gap is plurality of gaps,
wherein the substrate of each of the second memory dies includes one or more of the plurality of trenches on the upper surface of the substrate, and
wherein the plurality of gaps overlaps the plurality of trenches in the vertical direction.

15. The semiconductor package according to claim 13, wherein the at least one trench is a plurality of trenches, and the at least one gap is plurality of gaps,
wherein the substrate of each of the second memory dies includes one or more of the plurality of trenches on the lower surface of the substrate, and
wherein the plurality of gaps overlaps the plurality of trenches in the vertical direction.

16. A semiconductor package comprising:
a buffer die;
middle core die stack units stacked in a vertical direction on the buffer die, each of the middle core die stack units comprising middle core dies stacked in the vertical direction;
a top core die stacked on the middle core die stack units; and
a molding member on the buffer die, the molding member covering sidewalls of the middle core die stack units and the top core die,
wherein each of the middle core dies comprises:
a first substrate;
a first bonding layer on a lower surface of the first substrate, the first bonding layer comprising a first bonding pad; and
a second bonding layer on an upper surface of the first substrate, the second bonding layer comprising a second bonding pad,
wherein at least one first gap is between an upper surface of the second bonding layer of a first middle core die, from among the middle core dies, and a lower surface of the first bonding layer of a second middle core die, from among the middle core dies,
wherein the first middle core die or the second middle core die includes at least one first trench that at least partially defines the at least one gap, and
wherein the molding member is in the at least one first gap.

17. The semiconductor package according to claim 16, wherein the top core die comprises:
a second substrate; and
a third bonding layer on a lower surface of the second substrate, the third bonding layer comprising a third bonding pad,
wherein a second gap is between an upper surface of the second bonding layer of an uppermost one of the middle core dies of an uppermost one of the middle core die stack units and a lower surface of the third bonding layer of the top core die,
wherein the uppermost one of the middle core dies includes a second trench that at least partially defines the second gap, and
wherein the molding member is in the second gap.

18. The semiconductor package according to claim 16, wherein each of the middle core dies comprises a through electrode extending through the first substrate, the through electrode electrically connected to the first bonding pad and the second bonding pad, and
wherein the top core die does not comprise any through electrode.

19. The semiconductor package according to claim 16, wherein the buffer die comprises:
a second substrate; and
a third bonding layer on an upper surface of the second substrate, the third bonding layer comprising a third bonding pad,
wherein an upper surface of the third bonding layer of the buffer die contacts a lower surface of the first bonding layer of a lowermost one of the middle core dies from among the middle core dies of the middle core die stack units.

20. The semiconductor package according to claim 16, wherein the at least one first gap is a plurality of first gaps, and
wherein the plurality of first gaps are arranged in a ring shape at edge portions of each of the middle core dies in a plan view.
